(19) United States
(12) Patent Application Publication
(10) Pub. No.: US 2006/0014391 A1
(43) Pub. Date: Jan. 19, 2006

(54) Method of manufacturing a semiconductor device using a cleaning composition

(76) Inventors: Kyung-Jin Lee, Seoul (KR); Seung-Hyun Ahn, Suwon-si (KR); Baik-Soon Choi, Anyang-si (KR); Kui-Jong Baek, Daejeon-si (KR); Woong Hahn, Gongju-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/176,276

(22) Filed: Jul. 8, 2005

(30) Foreign Application Priority Data
Jul. 14, 2004 (KR) 2004-54828

(51) Int. Cl. H01L 21/465

(52) U.S. Cl. 438/695; 438/745

(57) ABSTRACT

A metal-containing pattern structure is formed on a semiconductor substrate, and a cleaning composition is applied to the semiconductor substrate. The cleaning composition includes, based on a total weight of the cleaning composition, about 78 wt % to about 99.98 wt % of an acidic aqueous solution, about 0.01 wt % to about 11 wt % of a first chelating agent, and about 0.01 wt % to about 11 wt % of a second chelating agent. The metal-containing pattern structure includes an exposed first surface portion and a second surface portion covered with a polymer. Application of the cleaning solution forms a first corrosion-inhibition layer on the first surface portion of the metal-containing pattern structure, and removes the polymer from the second surface portion of the metal-containing pattern structure.

### CROSS REFERENCE TO RELATED APPLICATION

This application claims priority under 35 USC § 119 to Korean Patent Application No. 2004-54828 filed on Jul. 14, 2004, the content of which is incorporated herein by reference in its entirety.

### BACKGROUND OF THE INVENTION 1. Field of the Invention

The present invention relates to a method of manufacturing a semiconductor device, and more particularly, the present invention relates to a method of manufacturing a semiconductor device having a metal-containing pattern structure using the cleaning composition.

2. Description of the Related Art

A semiconductor device having a high integration degree and a rapid response speed is highly in demand for the development of information processing apparatus. Hence, a technology of manufacturing the semiconductor device has been developed to improve integration degree, reliability and response speed of the semiconductor device.

In order to improve response speed of the semiconductor device, a metal wiring recently includes tungsten (W) instead of tungsten silicide (WSix). In order to reduce a manufacturing cost, a 300 mm silicon wafer is used instead of a 200 mm silicon wafer. In a manufacturing process using the 300 mm silicon wafer, a single-type cleaning apparatus is preferable to a batch-type cleaning apparatus.

A semiconductor device having a high integration degree frequently utilizes a multi-layered and miniaturized conductive wiring pattern. Photolithography has been the most widely used technology in a formation of a conductive wiring pattern, and also in a formation of a pad or a contact to connect the conductive wiring patterns.

In photolithography, a photoresist pattern employed for an etching mask is formed on a layer and then the layer is etched through an etching process such as a plasma etching, a reactive ion etching (RIE), an ion milling, etc., thereby forming the conductive wiring pattern or the pad. After the etching process, the photoresist pattern is removed through an ashing process such as an oxygen plasma ashing.

An etching gas generally used in the etching process is reacted with the photoresist pattern and/or the layer being etched, the layer including aluminum (Al), tungsten (W), titanium (Ti), silicon oxide (SiOx), etc. As a result, a polymer such as a sidewall polymeric material and an organometallic residue is formed on a semiconductor substrate or a surface of a structure on the semiconductor substrate. The polymer remains on the semiconductor substrate even after the oxygen plasma ashing, and a conventional stripping agent such as methylene chloride, dimethylformamide, dimethylacetamide, pyrrolidone, dimethylsulfone, etc. may not remove the polymer. The polymer may contaminate the surface of the structure on the semiconductor substrate, and thus a manufacturing efficiency and reliability of a semiconductor device may be deteriorated. Therefore, a cleaning composition for sufficiently removing the polymer from the semiconductor substrate and/or the structure is required.

Tungsten (W) may be used for a material of a gate electrode or a bit line, instead of tungsten silicide (WSix) having relatively high resistance. In order to remove a polymer from a metal layer including tungsten, a conventional cleaning solution such as APM (standard cleaning solution, SC-1) or SPM (sulfuric acid stripper) may not be used because of corrosion of the tungsten. An organic stripper that does not corrode tungsten may be alternatively used, but the organic stripper may not sufficiently remove an oxide polymer. In addition, a cleaning process using the organic stripper requires a relatively high cleaning temperature of about 65° C. to about 85° C. The organic stripper may be not used for a single-type cleaning apparatus in a processing of a 300 mm silicon wafer.

In order to overcome problems of the organic stripper, new cleaning compositions including a fluorine-containing compound have been developed. U.S. Pat. No. 5,962,385 issued to Maruyama et al. discloses a cleaning composition including a corrosion-inhibition agent and other additives. Korea Laid-Open Patent Publication No. 2003-35207 discloses a cleaning composition including ammonium hydroxide, hydrogen fluoride, acetic acid and deionized water, and having a pH range of about 7 to about 12. U.S. Pat. No. 5,780,363 issued to Delehanty et al. discloses a cleaning composition including sulfuric acid, hydrogen peroxide and hydrogen fluoride. The above-disclosed cleaning compositions can effectively remove a polymer remaining after an etching process, but can corrode a metal layer (e.g. aluminum, titanium, tungsten, etc.), an insulation layer and a polysilicon layer.

### SUMMARY OF THE INVENTION

In accordance with an aspect of the present invention, a metal-containing pattern structure is formed on a semiconductor substrate, and a cleaning composition is applied to the semiconductor substrate. The cleaning composition includes, based on a total weight of the cleaning composition, about 78 wt % to about 99.98 wt % of an acidic aqueous solution, about 0.01 wt % to about 11 wt % of a first chelating agent, and about 0.01 wt % to about 11 wt % of a second chelating agent. The metal-containing pattern structure includes an exposed first surface portion and a second surface portion covered with a polymer. Application of the cleaning solution forms a first corrosion-inhibition layer on the first surface portion of the metal-containing pattern structure, and removes the polymer from the second surface portion of the metal-containing pattern structure.

### BRIEF DESCRIPTION OF THE DRAWINGS

The above and other features and advantages of the present invention will become readily apparent by reference to the following detailed description when considered in conjunction with the accompanying drawings wherein:

FIGS. 1 and 2 are cross-sectional views illustrating a mechanism of a metal corrosion inhibition of a first chelating agent and a second chelating agent;

FIG. 3 is a flow chart illustrating a method of cleaning a metal layer on a semiconductor substrate using a cleaning composition according to one exemplary embodiment of the present invention;

FIG. 4 is a cross-sectional view illustrating a method of forming a word line in a semiconductor device according to one exemplary embodiment of the present invention;

FIG. 5 is a graph illustrating an etch rate of an aluminum layer relative to a concentration of hydrogen fluoride;

FIG. 6 is a graph illustrating an etch rate of an tungsten layer relative to a concentration of hydrogen peroxide;

FIGS. 7 and 8 are SEM pictures illustrating a cleaned surface of a contact according to types of cleaning compositions; and

FIGS. 9 and 10 are SEM pictures illustrating damage of an aluminum pattern according to an existence or absence of a chelating agent.

### DETAILED DESCRIPTION OF THE INVENTION

The present invention now will be described further hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, a region or a substrate is referred to as being “on” or “onto” another element, it can be directly on the other element or intervening elements may also be present.

Cleaning Composition

After a metal layer and an oxide layer formed on a semiconductor substrate are etched by a dry etching process, particles may remain on the metal layer, the oxide layer and the semiconductor substrate. In order to remove the particles without damages to the metal layer, the oxide layer and the semiconductor substrate, a cleaning composition has some properties as follows:

A peroxide compound included in the cleaning composition may normally corrode a metal layer including tungsten (W). Thus, the cleaning composition of the present invention may prevent corrosion of the metal layer of tungsten exposed in a cleaning process.

When the cleaning composition includes an excessive fluorine-containing compound, the composition for cleaning the semiconductor substrate may normally corrode a metal layer including aluminum (Al). Thus, the cleaning composition of the present invention may prevent corrosion of the metal layer of aluminum exposed in the cleaning process.

After etching a metal layer, remaining particles may include a large amount of a polymer, such as a metallic polymer, an oxide polymer or an organic polymer. A conventional stripper may not remove the polymer from the metal layer and/or the semiconductor substrate. Thus, the cleaning composition of the present invention may thoroughly remove the polymer from the metal layer and/or the semiconductor substrate.

When an oxide layer formed beneath a metal layer is excessively etched, the metal layer may be lifted and an aspect ratio of the metal layer may become greater. As a result, a defect such as a void may be generated in an insulation layer formed on the metal layer in a successive process. Thus, the cleaning composition of the present invention may advantageously control an etching rate of the oxide layer.

In one embodiment of the present invention, in order to satisfy above-described requirements, a cleaning composition includes an acidic aqueous solution, a first chelating agent and a second chelating agent. When the cleaning composition includes less than about 78 wt % of the acidic aqueous solution, greater than about 11 wt % of the first chelating agent, and greater than about 11 wt % of the second chelating agent based on a total weight of the cleaning composition, a polymer removal ability of the cleaning composition may be poor and also a corrosion inhibiting ability of the cleaning composition may not substantially increase. In addition, when the cleaning composition includes greater than about 99.98 wt % of the acidic aqueous solution, less than about 0.01 wt % of the first chelating agent, and less than about 0.01 wt % of the second chelating agent based on a total weight of the cleaning composition, the corrosion inhibiting ability of the cleaning composition may be poor. Therefore, the cleaning composition may preferably include about 78 wt % to about 99.98 wt % of the acidic aqueous solution, about 0.01 wt % to about 11 wt % of the first chelating agent, and about 0.01 wt % to about 11 wt % of the second chelating agent based on a total weight of the cleaning composition, more preferably, about 90 wt % to about 99.8 wt % of the acidic aqueous solution, about 0.1 wt % to about 5 wt % of the first chelating agent, and about 0.1 wt % to about 5 wt % of the second chelating agent.

In order to obtain sufficient polymer removal ability, a pH of the cleaning composition may be in a range of about 0.1 to about 6, preferably, in a range of about 0.1 to about 2.

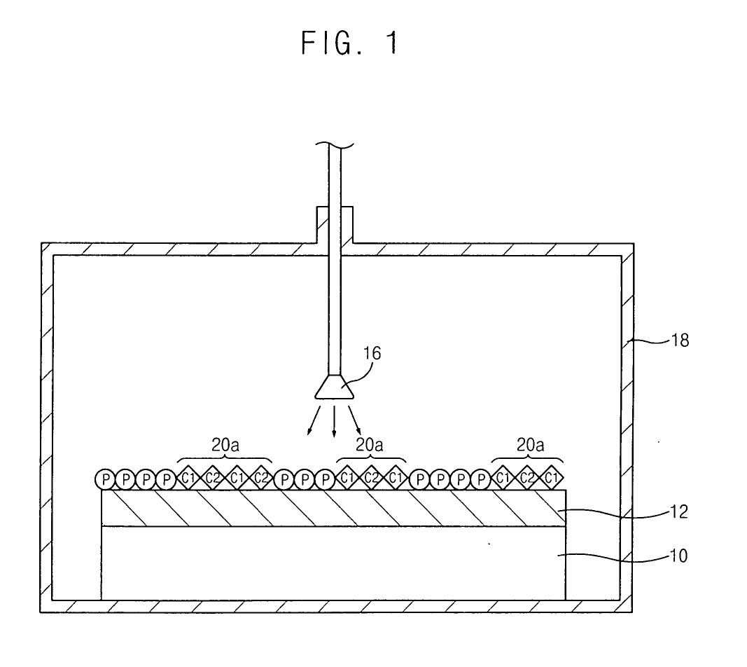

FIGS. 1 and 2 are cross-sectional views illustrating a mechanism of a metal corrosion inhibition of the first chelating agent and the second chelating agent contained in the cleaning composition. In FIGS. 1 and 2, the cleaning composition is provided onto a metal pattern 12 on a semiconductor substrate 10 loaded in a chamber 18 through a nozzle 16.

Referring to FIG. 1, the first chelating agent (C1) and the second chelating agent (C2) may inhibit a corrosion of the metal pattern 12 formed on the semiconductor substrate 10. The first chelating agent (C1) and the second chelating agent (C2) may be adsorbed to a first surface portion of the metal pattern 12 where a polymer (P) is not attached thereto, thereby forming a first corrosion-inhibition layer 20a on the metal pattern 12. Thus, the cleaning composition may prevent damage to the metal pattern 12 in a cleaning process.

Referring to FIG. 2, the first chelating agent (C1) and the second chelating agent (C2) may form a second corrosion-inhibition layer 20b on a second surface portion of the metal pattern 12 exposed by removing the polymer (P) originally adsorbed thereto. Thus, the cleaning composition may prevent a reaction of the acidic aqueous solution with the metal pattern 12, thereby inhibiting a corrosion of the metal pattern 12 in the cleaning process.

According to the present invention, the first chelating agent may include an azole compound, an amine compound, a sulfur-containing compound, etc. These can be used alone or in a mixture thereof.

Examples of the azole compound may include a triazole compound, a benzotriazole compound, an imidazole compound, a tetrazole compound, a thiazole compound, an oxazole compound, a pyrazole compound, etc. These can be used alone or in a mixture thereof.

Examples of the triazole compound may include triazole, 1H-1,2,3-triazole, 1,2,3-triazole-4,5-dicarboxylic acid, 1,2,4-triazole, 1H-1,2,4-triazole-3-thiol, 3-amino-triazole, etc. These can be used alone or in a mixture thereof.

Examples of the benzotriazole compound may include benzotriazole, 1-amino-benzotriazole, 1-hydroxy-benzotriazole, 5-methyl-1H-benzotriazole, benzotriazole-5-carboxylic acid, etc. These can be used alone or in a mixture thereof.

Examples of the imidazole compound may include imidazole, 1-methyl imidazole, benzimidazole, 1-methyl-benzimidazole, 2-methyl-benzimidazole, 5-methyl-benzimidazole, etc. These can be used alone or in a mixture thereof.

Examples of the tetrazole compound may include 1H-tetrazole, 1H-tetrazole-5-acetic acid, 5-amino-tetrazole, etc. These can be used alone or in a mixture thereof.

Examples of the thiazole compound may include benzothiazole, 2-methyl-benzothiazole, 2-amino-benzothiazole, 6-amino-benzothiazole, 2-mercapto-benzothiazole, etc. These can be used alone or in a mixture thereof.

Examples of the oxazole compound may include isoxazole, benzoxazole, 2-methyl-benzoxazole, 2-mercapto-benzoxazole, etc. These can be used alone or in a mixture thereof.

Examples of the pyrazole compound may include pyrazole, 4-pyrazole-carboxilic acid, etc. These can be used alone or in a mixture thereof.

Examples of the amine compound may include methylamine, diethylamine, n-decylamine, morpholine, allylamine, pyridine, quinoline, imidazoline, hexamethyleneimene-m-nitrobenzoate, dicyclohexamine nitrite, 1-ethylamino-2-octadecylimidazoline, etc. These can be used alone or in a mixture thereof.

Examples of the sulfur-containing compound may include benzylmercaptan, phenylthiourea, di-sec-butylsulfide, diphenylsulfoxide, etc. These can be used alone or in a mixture thereof.

According to the present invention, the second chelating agent may include an amino acid compound.

Examples of the amino acid compound may include diethylenetriaminepentaacetic acid, glycine, alanine, valine, leucine, isoleucine, serine, threonine, tyrosine, phenylalanine, tryptophan, aspartic acid, glutamic acid, glutamine, asparagine, lysine, arginine, histidine, hydroxylysine, cysteine, methionine, cystine, proline, sulfamic acid, hydroxyproline, etc. These can be used alone or in a mixture thereof.

When the cleaning composition of the present invention includes less than about 0.01 wt % of the first chelating agent and less than about 0.01 wt % of the second chelating agent based on a total weight of the cleaning composition, the corrosion inhibiting ability of the cleaning composition may be poor and thus the metal pattern 12 may be damaged by the acidic aqueous solution. When the cleaning composition includes greater than about 11 wt % of the first chelating agent and greater than about 11 wt % of the second chelating agent based on a total weight of the cleaning composition, a corrosion inhibiting ability of the cleaning composition may not substantially increase and be saturated. In addition, a peroxide compound included in the cleaning composition may be reacted with the first chelating agent and the second chelating agent, thereby discoloring the cleaning composition and generating gas. Therefore, the cleaning composition may preferably include about 0.01 wt % to about 11 wt % of the first chelating agent and about 0.01 wt % to about 11 wt % of the second chelating agent based on a total weight of the cleaning composition, more preferably, about 0.1 wt % to about 5 wt % of the first chelating agent and about 0.1 wt % to about 5 wt % of the second chelating agent.

According to the present invention, the cleaning composition includes an acidic aqueous solution in order to remove a polymer, for example, a metallic polymer, an oxide polymer or an organic polymer. The acidic aqueous solution may include sulfuric acid, a peroxide compound, a fluorine-containing compound and pure water.

When the cleaning composition includes less than about 0.01 wt % of the sulfuric acid based on a total weight of the cleaning composition, an organic polymer removal ability of the cleaning composition may be deteriorated. When the cleaning composition includes greater than about 30 wt % of the sulfuric acid, the cleaning composition may damage the metal pattern 12. Therefore, the cleaning composition may preferably include about 0.01 wt % to about 30 wt % of the sulfuric acid based on a total weight of the cleaning composition, more preferably, about 0.1 wt % to about 10 wt % of the sulfuric acid.

Examples of the peroxide compound of the present invention may include hydrogen peroxide, ozone, peroxosulfuric acid, peroxoboric acid, peroxophosphoric acid, peracetic acid, etc.

When the cleaning composition includes less than about 0.01 wt % of the peroxide compound based on a total weight of the cleaning composition, the organic polymer removal ability of the cleaning composition may be deteriorated. When the cleaning composition includes greater than about 20 wt % of the peroxide compound, the cleaning composition may damage the metal pattern 12. Therefore, the cleaning composition may preferably include about 0.01 wt % to about 20 wt % of the peroxide compound based on a total weight of the cleaning composition, more preferably, about 0.1 wt % to about 10 wt % of the peroxide compound.

Examples of the fluorine-containing compound of the present invention may include hydrogen fluoride (HF), ammonium fluoride (NH₄F), fluoroboric acid (HBF₄), etc.

When the cleaning composition includes less than about 0.001 wt % of the fluorine-containing compound based on a total weight of the cleaning composition, the oxide polymer removal ability of the cleaning composition may be deteriorated. When the cleaning composition includes greater than about 5 wt % of the fluorine-containing compound, the cleaning composition may excessively etch a silicon oxide layer, a titanium nitride layer and/or an aluminum layer to thereby generate failures of a semiconductor device. Therefore, the cleaning composition may preferably include about 0.001 wt % to about 5 wt % of the fluorine-containing compound based on a total weight of the cleaning composition, more preferably, about 0.01 wt % to about 2 wt % of the fluorine-containing compound.

According to the present invention, the cleaning composition includes pure water, preferably, ultra pure water.

Method of Cleaning a Metal Layer on a Semiconductor Substrate

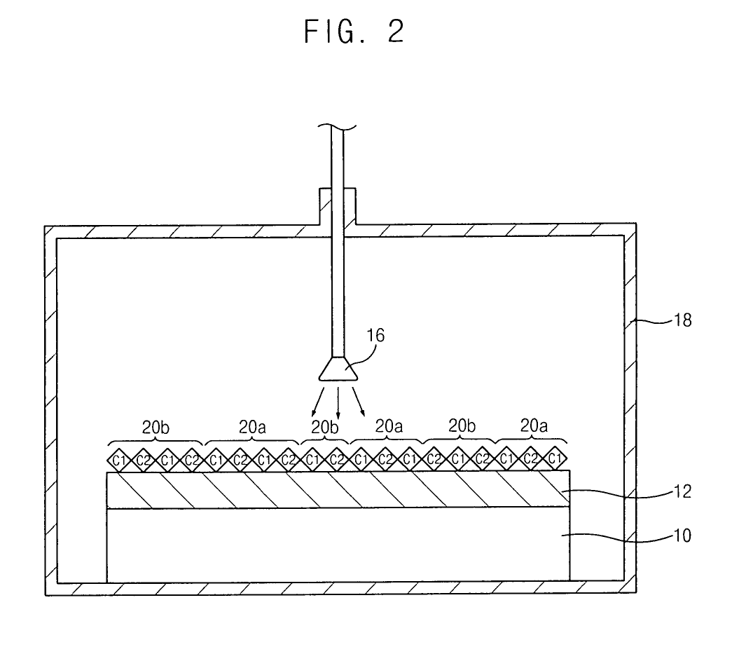

FIG. 3 is a flow chart illustrating a method of cleaning a metal layer on a semiconductor substrate using a cleaning composition according to one exemplary embodiment of the present invention.

Referring to FIG. 3, a cleaning composition including an acidic aqueous solution, a first chelating agent and a second chelating agent may be provided onto the metal layer formed on the semiconductor substrate in step S10. The first chelating agent and the second chelating agent may form a first corrosion-inhibition layer on a first surface portion of the metal layer where a polymer is not attached thereto, and simultaneously the acidic aqueous solution may remove the polymer, such as an organic polymer, an oxide polymer or a metallic polymer, attached to a second surface portion of the metal layer in step S20. Particularly, a fluorine-containing compound in the acidic aqueous solution may remove the oxide polymer, and a peroxide compound and sulfuric acid in the acidic aqueous solution may remove the organic polymer and the metallic polymer.

The first chelating agent and the second chelating agent may be adsorbed onto the second surface portion of the metal layer exposed according to removal of the polymer originally attached onto the second surface portion of the metal pattern, thereby forming a second corrosion-inhibition layer on the second surface portion of the metal layer in step S30. Thus, the first chelating agent and the second chelating agent may prevent damage to the metal layer from which the polymer is removed by the acidic aqueous solution. Here, the metal layer may include tungsten (W), titanium nitride (TiNx), titanium (Ti), copper (Cu), aluminum (Al), etc. For example, the cleaning composition is used for cleaning a metal layer of tungsten or a metal layer of aluminum.

After cleaning the metal layer on the semiconductor substrate using the cleaning composition, the semiconductor substrate may be rinsed using deionized water so that a remaining cleaning composition may be removed from the substrate and the metal layer in step S40. In order to remove remaining deionized water, the semiconductor substrate may be dried in step S50. Here, the polymer on the metal layer may be dissolved in the cleaning composition or the polymer may be loosely attached onto the metal layer. Thus, most of the polymer may be removed after rinsing the semiconductor including the metal layer thereon.

A batch-type cleaning apparatus or a single-type cleaning apparatus may be employed for a cleaning process. The single-type cleaning apparatus may be advantageously employed for the cleaning process because it may be effectively clean the metal layer using the cleaning composition.

According to the present invention, a temperature of the cleaning process for the metal layer may be in a range of about 10° C. to about 40° C. When a cleaning temperature is less than about 10° C., time may be excessively required for removing the polymer from the metal layer. When a cleaning temperature is greater than about 40° C., the metal layer and/or an oxide layer formed on the semiconductor substrate may be damaged.

Method of Manufacturing a Semiconductor Device

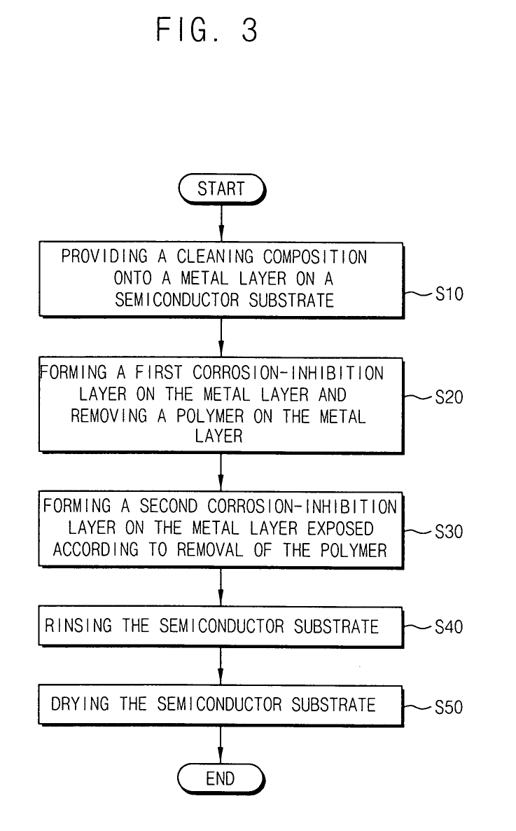

FIG. 4 is a cross-sectional view illustrating a method of forming a word line in a semiconductor device according to one exemplary embodiment of the present invention.

Referring to FIG. 4, a photoresist pattern (not shown) may be formed on a semiconductor substrate 100 including a gate oxide layer (not shown), a gate conductive layer (not shown) and a gate mask layer (not shown). The gate oxide layer, the gate conductive layer and the gate mask layer may be etched using the photoresist pattern as an etching mask, thereby forming a gate structure 110 on the semiconductor substrate 100. The gate structure 110 may include a gate oxide layer pattern 104a, a gate conductive layer pattern 106a and a gate mask layer 108a.

A large amount of a polymer (P) may remain on a surface of the gate structure 110. The polymer (P) may be generated in etching of an oxide layer, a polysilicon layer, a tungsten layer, an aluminum layer, a mask layer and a photoresist pattern. Thus, examples of the polymer (P) may include an oxide polymer, an organic polymer, a metallic polymer, etc.

The organic polymer and the metallic polymer may be formed in a formation of the gate conductive layer pattern 106a, and the oxide polymer may be formed in a formation of the gate oxide layer pattern 104a. The polymer (P) may be attached to a surface of the semiconductor substrate 100 and a surface of the gate structure 110. The polymer (P) may cause an increase of an electrical resistance and a short circuit between the word lines. Therefore, the polymer (P) is removed to prevent electrical failures of a semiconductor device.

According to the present invention, the polymer (P) attached to a sidewall of the gate structure 110 may be removed without damage to the gate conductive layer pattern 106a including tungsten or aluminum and the gate oxide layer pattern 104a. A cleaning process for removing the polymer (P) will be fully described hereinafter.

A cleaning composition may be prepared by adding a first chelating agent and a second chelating agent into an acidic aqueous solution. According to one exemplary embodiment of the present invention, the cleaning composition may include about 0.1 wt % to about 10 wt % of sulfuric acid, about 0.1 wt % to about 10 wt % of a peroxide compound, about 0.01 wt % to about 2 wt % of a fluorine-containing compound, about 0.1 wt % to about 5 wt % of the first chelating agent, about 0.1 wt % to about 5 wt % of the second chelating agent and residual pure water. The cleaning composition may be substantially identical to the above-described cleaning composition.

After a preparation of the cleaning composition, the semiconductor substrate 100 including the gate structure 110 may be cleaned using the cleaning composition so that the polymer (P) on the surface of the gate structure 110 may be removed. A batch-type cleaning apparatus or a single-type cleaning apparatus may be employed. The single-type cleaning apparatus may be advantageously employed for removing the polymer (P) because the polymer (P) may be more effectively removed from the gate structure 110.

According to one exemplary embodiment of the present invention, the semiconductor substrate 100 may be introduced into the single-type cleaning apparatus. The cleaning composition having a temperature of about 10° C. to about 40° C. may be sprayed onto the semiconductor substrate 100. While rotating the semiconductor substrate 100 or stopping the semiconductor substrate 100, the cleaning composition may make contact with the gate structure 110 and the semiconductor substrate 100 to thereby remove the polymer (P) from the surface of the gate structure 110 and the surface of the semiconductor substrate 100. The cleaning composition may make contact with the semiconductor substrate 100 for about 0.01 minutes to about 5 minutes, more preferably, for about 0.1 minutes to about 2 minutes. Here, the fluorine-containing compound in the cleaning composition may remove the oxide polymer from the surface of the gate structure 110 and/or and the semiconductor substrate 100. The peroxide compound and the sulfuric acid may remove the organic polymer and the metallic polymer from the surface of the gate structure 110 and/or and the semiconductor substrate 100. The first chelating agent and the second chelating agent may be attached to a first surface portion of the gate structure 110, the polymer (P) is not originally attached, thereby inhibiting corrosion of the gate structure 110. The first chelating agent and the second chelating agent may be attached to a second surface portion of the gate structure 110 exposed according to removal of the polymer attached thereto, thereby inhibiting corrosion of the gate structure 110.

The cleaning composition remaining on the semiconductor substrate 100 and/or the gate structure 110 may be removed by rinsing the semiconductor substrate 100 including the gate structure 110. Here, the polymer (P) on the surface of the gate structure 110 may be dissolved in the cleaning composition or the polymer (P) may be loosely attached to the surface of the gate structure 110. Thus, most of the polymer may be removed after rinsing the semiconductor substrate 100 using deionized water. In order to remove remaining deionized water from the gate structure 110 and the semiconductor substrate 100, the semiconductor substrate 100 having the gate structure 110 thereon may be dried. Subsequently, a word line including the gate structure 110 may be formed on the semiconductor substrate 100.

According to the present invention, the word line may include a minute amount of the polymer thereon and an undamaged metal pattern, and thus electrical characteristics of the word line may be highly enhanced. Besides the semiconductor device including the word line, a semiconductor device including a bit line, a metal wiring, a pad, a contact, a plug, etc. may be manufactured using the cleaning composition of the present invention.

A cleaning composition of the present invention will be further described through Examples and Comparative Examples.

Preparing of the Cleaning Composition

### EXAMPLE 1

About 9.0 wt % of sulfuric acid, about 4.0 wt % of hydrogen peroxide, about 0.01 wt % of hydrogen fluoride, about 2.0 wt % of triazole, about 2.0 wt % of glutamic acid and residual pure water were mixed to prepare a cleaning composition.

### EXAMPLES 2 TO 10

Cleaning compositions were prepared by performing the same processes as in Example 1, except for contents of the hydrogen fluoride, the hydrogen peroxide and the chelating agents. Types and contents of the cleaning composition are shown in the following Table 1.

### Comparative Examples 1 to 15

Cleaning compositions were prepared by changing an existence and a type of a chelating agent, and a content of the cleaning composition. Types and contents of the cleaning composition are shown in the following Table 1.

TABLE 1

| | Sulfuric | Hydrogen | Hydrogen | Chelating Agent | |
|---|---|---|---|---|---|
| | Acid | Peroxide | Fluoride | Type | Content |
| Example 1 | 9 | 4.0 | 0.01 | Triazole | 2.0 |
| | | | | Glutamic Acid | 2.0 |
| Example 2 | 9 | 4.0 | 0.03 | Triazole | 2.0 |
| | | | | Glutamic Acid | 2.0 |
| Example 3 | 9 | 1.2 | 0.03 | Triazole | 2.0 |
| | | | | Glutamic Acid | 2.0 |
| Example 4 | 9 | 4.0 | 0.01 | Triazole | 7.0 |
| | | | | Glutamic Acid | 7.0 |
| Example 5 | 9 | 3.8 | 0.01 | Triazole | 2.0 |
| | | | | Glutamic Acid | 2.0 |
| Example 6 | 9 | 3.8 | 0.03 | Triazole | 1.0 |
| | | | | Glutamic Acid | 1.0 |
| Example 7 | 9 | 3.8 | 0.03 | Triazole | 2.0 |
| | | | | Glutamic Acid | 2.0 |
| Example 8 | 9 | 3.8 | 0.03 | Triazole | 3.0 |
| | | | | Glutamic Acid | 3.0 |
| Example 9 | 9 | 3.8 | 0.03 | Triazole | 5.0 |
| | | | | Glutamic Acid | 5.0 |
| Example 10 | 9 | 3.8 | 0.03 | Triazole | 10 |
| | | | | Glutamic Acid | 10 |
| Comparative | 9 | 4.0 | 0.01 | Triazole | 2.0 |
| Example 1 | | | | | |
| Comparative | 9 | 4.0 | 0.01 | Glutamic Acid | 2.0 |
| Example 2 | | | | | |
| Comparative | 9 | 4.0 | 0.01 | Benzotriazole | 2.0 |
| Example 3 | | | | | |
| Comparative | 9 | 4.0 | 0.03 | Triazole | 2.0 |
| Example 4 | | | | | |
| Comparative | 9 | 4.0 | 0.03 | Glutamic Acid | 2.0 |
| Example 5 | | | | | |
| Comparative | 9 | 4.0 | 0.03 | Benzotriazole | 2.0 |
| Example 6 | | | | | |
| Comparative | 9 | 4.0 | 0.01 | Fluorine- | 2.0 |
| Example 7 | | | | containing | |
| | | | | Surfactant | |
| Comparative | 9 | 4.0 | 0.03 | Fluorine- | 2.0 |
| Example 8 | | | | containing | |
| | | | | Surfactant | |
| Comparative | 9 | 1.2 | 0.03 | — | — |
| Example 9 | | | | | |
| Comparative | 6 | 4.0 | 0.01 | — | — |
| Example 10 | | | | | |
| Comparative | 9 | 4.0 | 0.01 | — | — |
| Example 11 | | | | | |
| Comparative | 9 | 4.0 | 0.03 | — | — |
| Example 12 | | | | | |
| Comparative | 9 | 4.0 | 0.01 | Triazole | 12.0 |
| Example 13 | | | | Glutamic Acid | 12.0 |
| Comparative | 9 | 3.8 | 0.01 | — | — |
| Example 14 | | | | | |
| Comparative | 9 | 3.8 | 0.03 | — | — |
| Example 15 | | | | | |

Estimation of an Etch Rate Relative to a Concentration of Hydrogen Fluoride

Etch rates of aluminum layers were estimated for the cleaning compositions according to Example 1, Example 2, Comparative Example 11 and Comparative Example 12.

An aluminum layer was formed on a metal barrier layer by a chemical vapor deposition (CVD) process after the metal barrier layer was formed on an oxide layer positioned on a silicon substrate. The aluminum layer had a thickness of about 3,500 Å.

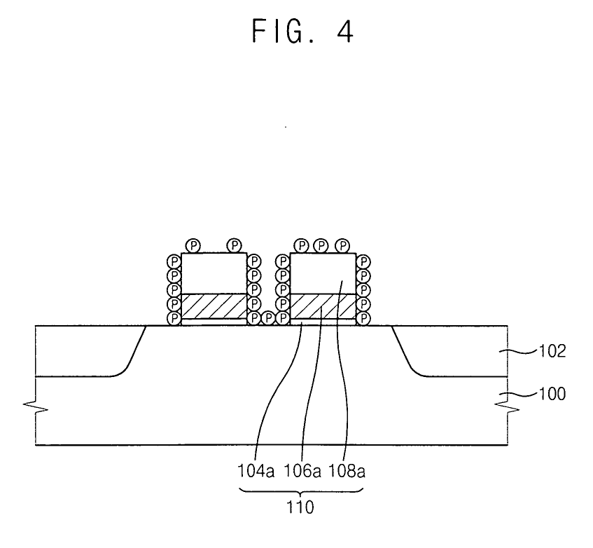

FIG. 5 is a graph illustrating an etch rate of an aluminum layer relative to a concentration of hydrogen fluoride.

Referring to FIG. 5, the etch rates of the aluminum layers cleaned using cleaning compositions including about 0.01 wt % of the hydrogen fluoride according to Example 1 and Comparative Example 11 were substantially lower by about 50% to about 65% than those of aluminum layers cleaned using cleaning compositions including about 0.03 wt % of the hydrogen fluoride according to Example 2 and Comparative Example 12. Therefore, the etch rates of the aluminum layers may increase relative to an increase of the concentration of the hydrogen fluoride.

In addition, etch rates of aluminum layers cleaned using cleaning compositions including chelating agents according to Examples 1 and 2 were substantially lower than those of aluminum layers cleaned using cleaning compositions not including chelating agents according to Comparative Examples 11 and 12. The cleaning compositions of the present invention include chelating agents and the chelating agents may inhibit a corrosion of the aluminum layers. Therefore, the cleaning composition including the chelating agent may reduce the etch rates of the aluminum layers. Accordingly, the cleaning composition of the present invention may prevent damage to an aluminum layer in a semiconductor device and the concentration of the hydrogen fluoride may affect damage to the aluminum layer.

Estimation of an Etch Rate Relative to a Concentration of Hydrogen Peroxide

Etch rates of tungsten layers were estimated for the cleaning compositions according to Example 2, Example 3, Comparative Example 9 and Comparative Example 12.

A tungsten layer was formed on a metal barrier layer by a CVD process after the metal barrier layer was formed on an oxide layer formed on a silicon substrate. The tungsten layer has a thickness of about 600 Å.

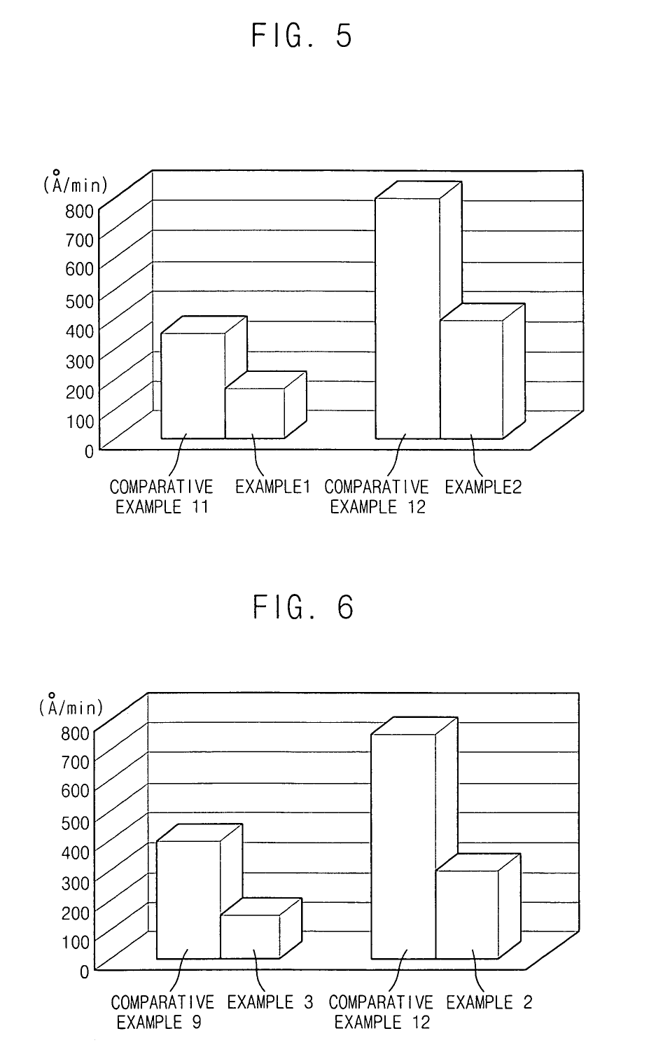

FIG. 6 is a graph illustrating an etch rate of a tungsten layer relative to a concentration of hydrogen peroxide.

Referring to FIG. 6, the etch rates of the tungsten layers cleaned using cleaning compositions including about 1.2 wt % of the hydrogen peroxide according to Example 3 and Comparative Example 9 were substantially lower by about 50% to about 65% than those of tungsten layers cleaned using cleaning compositions including about 4.0 wt % of the hydrogen peroxide according to Example 2 and Comparative Example 12. Therefore, the etch rates of the tungsten layers may increase relative to an increase of the concentration of the hydrogen peroxide.

In addition, etch rates of tungsten layers cleaned using cleaning compositions including chelating agents according to Examples 2 and 3 were substantially lower than those of tungsten layers cleaned using cleaning compositions not including chelating agents according to Comparative Examples 9 and 12. The cleaning compositions of the present invention include chelating agents and the chelating agents may inhibit a corrosion of the tungsten layers. Therefore, the cleaning composition including the chelating agent may reduce the etch rates of the tungsten layers. Accordingly, the cleaning composition of the present invention may prevent damage to a tungsten layer in a semiconductor device and the concentration of the hydrogen peroxide may affect damage to the tungsten layer.

Estimation of Stability of a Cleaning Composition

Stability of cleaning compositions according to Example 1, Example 4 and Comparative Example 13 was estimated as shown in the following Table 2.

After a preparation of the cleaning compositions, the stability of the cleaning compositions was estimated by measuring an amount of gas generated in the preparation of the cleaning compositions and by observing a discoloration of the cleaning compositions.

TABLE 2

| | Example 1 | Example 4 | Comparative Example 13 |
|---|---|---|---|
| Stability | Excellent | Good | Bad |

As shown in Table 2, the cleaning composition including about 0.01 wt % to about 11 wt % of a first chelating agent and about 0.01 wt % to about 11 wt % of a second chelating agent may have an enhanced stability.

According to the present invention, the cleaning composition may include about 0.01 wt % to about 11 wt % of the first chelating agent and about 0.01 wt % to about 11 wt % of the second chelating agent, more preferably, about 0.1 wt % to about 5 wt % of the first chelating agent and about 0.1 wt % to about 5 wt % of the second chelating agent.

Estimation of a Cleaning Effect on a Contact

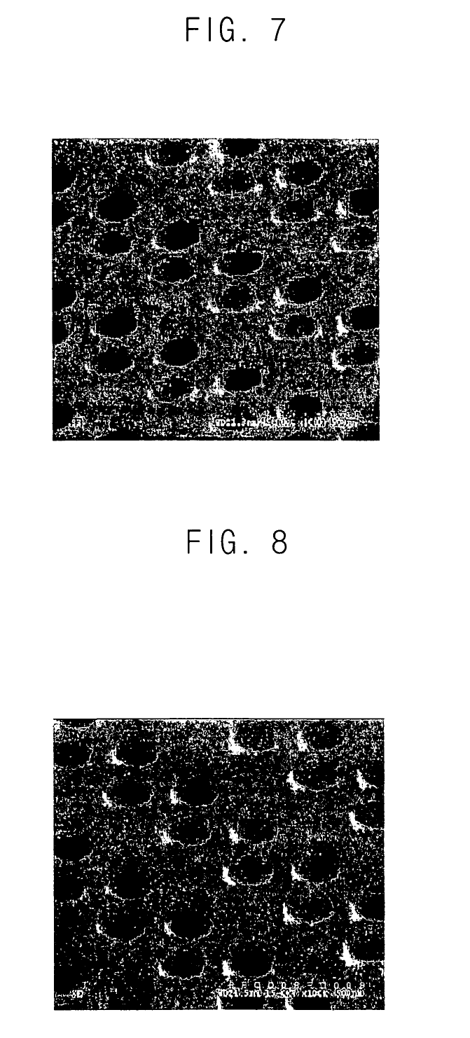

FIGS. 7 and 8 are SEM pictures illustrating a cleaned surface of a contact according to types of cleaning compositions.

FIG. 7 is a SEM picture illustrating a surface of a contact including tungsten after cleaning the contact using the cleaning composition according to Comparative Example 12. Particularly, after forming the contact by an etching process and an ashing process, a semiconductor substrate including the contact was immersed into a batch-type cleaning apparatus including the cleaning composition at a temperature of about 25° C. for about 30 seconds. The semiconductor substrate was rinsed with ultra pure water and then the semiconductor substrate was dried. FIG. 8 is a SEM picture illustrating a surface of a contact including tungsten after cleaning the contact by performing a procedure substantially identical to that described with reference to FIG. 7 except that the cleaning composition according to Example 2 was used.

Referring to FIG. 7, particles such as a polymer and other residues may remain on the contact after cleaning the contact using the cleaning composition according to Comparative Example 12. Referring to FIG. 8, particles may be removed using the cleaning composition according to Example 2.

Therefore, a cleaning composition and a method of cleaning a metal layer on a semiconductor substrate may have an enhanced polymer removal ability compared with a conventional cleaning composition and a conventional cleaning method.

Estimation of Damage to a Sidewall of an Aluminum Pattern

After cleaning an aluminum pattern using cleaning compositions according to Example 2 and Comparative Example 12, damage to the aluminum pattern was estimated.

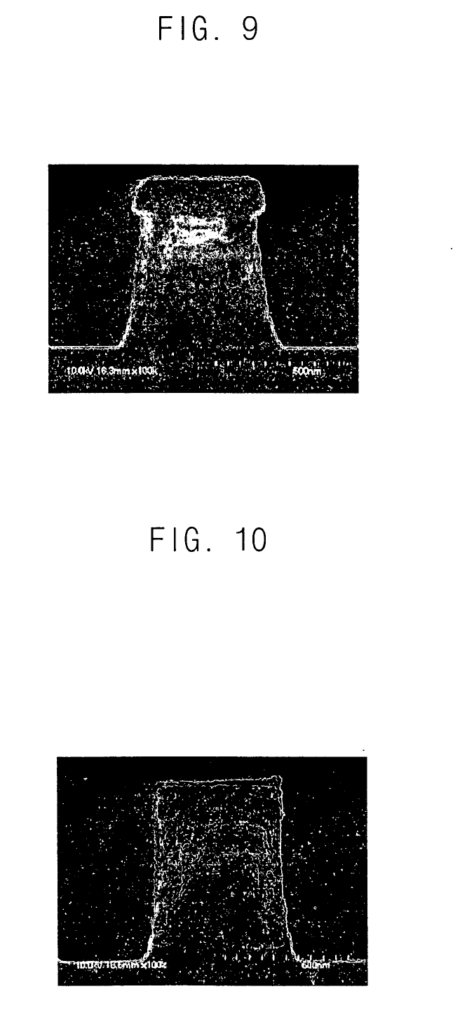

FIGS. 9 and 10 are SEM pictures illustrating damage of an aluminum pattern according to an existence or absence of a chelating agent.

The aluminum pattern on a semiconductor substrate was formed through the following procedure. An oxide layer was formed on the silicon substrate and then a contact hole was formed through the oxide layer. A metal barrier layer was formed to cover the oxide layer and a sidewall of the contact hole. An aluminum layer was formed on the metal barrier layer to fill up the contact hole and then a silicon nitride layer serving as a hard mask was formed on the aluminum layer. After a photoresist pattern was formed on the silicon nitride layer, the silicon nitride layer was etched using the photoresist pattern as an etching mask. Then, an ashing process was performed to remove the photoresist pattern. The aluminum layer was etched using the silicon nitride layer as an etching mask, and then the silicon nitride layer was removed. As a result, the aluminum pattern serving as a contact or a pad was formed on the semiconductor substrate.

The semiconductor substrate including the aluminum pattern was immersed into a batch-type cleaning apparatus including the cleaning composition at a temperature of about 25° C. for about 60 seconds. The semiconductor substrate was rinsed with ultra pure water, and then the semiconductor substrate was dried.

FIG. 9 is a SEM picture illustrating damage to a sidewall of the aluminum pattern from the cleaning composition according to Comparative Example 12. FIG. 10 is a SEM picture illustrating damage to a sidewall of the aluminum pattern from the cleaning composition according to Example 2.

Referring to FIGS. 9 and 10, the sidewall of the aluminum pattern in FIG. 9 was damaged, whereas the sidewall of the aluminum pattern in FIG. 10 was not damaged. Therefore, a cleaning composition including a chelating agent may reduce damage to a metal layer such as the aluminum pattern compared with a cleaning composition not including the chelating agent.

Estimation of an Etch Rate of a Tungsten Layer and an Aluminum Layer

After cleaning a tungsten layer and an aluminum layer using cleaning compositions according to Examples 1, 2 and 5 to 10, Comparative Examples 1 to 8, 11, 12, 14 and 15, damages to the tungsten layer and the aluminum layer were estimated as shown in Table 3.

The tungsten layer or the aluminum layer was formed through the following procedure. An oxide layer was formed on a silicon substrate, and then a metal barrier layer was formed on the oxide layer. A tungsten layer having a thickness of about 600 Å or an aluminum layer having a thickness of about 3,500 Å was formed on the metal barrier layer.

A semiconductor substrate including the tungsten layer or the aluminum layer was immersed into a batch-type cleaning apparatus including the cleaning composition at a temperature of about 25° C. for about 30 seconds. The semiconductor substrate was rinsed with ultra pure water, and then the semiconductor substrate was dried.

TABLE 3

| | Etch Rate of | Etch Rate of |
|---|---|---|
| | Tungsten Layer | Aluminum Layer |
| | [Å/min] | [Å/min] |
| Example 1 | 3.09 | 34.13 |
| Example 2 | 4.83 | 84.35 |
| Example 5 | 2.8 | 30.4 |
| Example 6 | 9.9 | 102.1 |
| Example 7 | 7.1 | 81.2 |
| Example 8 | 5.4 | 64.3 |
| Example 9 | 2.8 | 42.1 |
| Example 10 | 1.4 | 25.3 |
| Comparative Example 1 | 7.22 | 53.32 |
| Comparative Example 2 | 2.74 | 56.51 |
| Comparative Example 3 | 4.48 | 62.61 |
| Comparative Example 4 | 9.11 | 80.44 |
| Comparative Example 5 | 12 | 120.91 |
| Comparative Example 6 | 8.58 | 93.45 |
| Comparative Example 7 | 2.99 | 72.67 |
| Comparative Example 8 | 16.78 | 95.77 |
| Comparative Example 11 | 8.92 | 69.65 |
| Comparative Example 12 | 18.38 | 164.71 |
| Comparative Example 14 | 14 | 95.8 |
| Comparative Example 15 | 35 | 182.1 |

Example 1 and Comparative Examples 1 to 3, 7 and 11 in Group I were compared with each other. Example 2 and Comparative Examples 4 to 6, 8 and 12 in Group II were compared with each other. Each of Example 1 and Comparative Examples 1, 2, 3, 7 and 11 in Group I includes identical contents of sulfuric acid, hydrogen peroxide and hydrogen fluoride from one another, except for an existence and types of chelating agents. Each of Example 2 and Comparative Examples 4, 5, 6, 8 and 12 in Group II includes identical contents of sulfuric acid, hydrogen peroxide and hydrogen fluoride from one another, except for an existence and types of chelating agents. Examples 5 and 6, and Comparative Examples 14 and 15 in Group III were compared with each other. Each of Examples 5 and 6 and Comparative Examples 14 and 15 in Group III includes identical contents of sulfuric acid and hydrogen peroxide from one another, except for a content of hydrogen fluoride and an existence of chelating agents. Examples 6 to 10 in Group IV were compared with each other. Each of Examples 6, 7, 8, 9 and 10 in Group IV includes identical contents of sulfuric acid, hydrogen peroxide and hydrogen fluoride, and types of chelating agents from one another, except for contents of chelating agents.

Referring to Table 3, in Group I etch rates of the tungsten layer and the aluminum layer from the cleaning compositions including at least one chelating agent according to Example 1 and Comparative Examples 1 to 3, were substantially lower than those from the cleaning composition not including a chelating agent according to Comparative Example 11 and the cleaning composition including only a surfactant according to Comparative Example 7. Further, etch rates of the tungsten layer and the aluminum layer from the cleaning composition including two types of the chelating agent according to Example 1 were relatively lower than those from the cleaning compositions including one type of the chelating agent according to Comparative Examples 1 to 3.

In Group II, etch rates of the tungsten layer and the aluminum layer from the cleaning compositions including at least one chelating agent according to Example 2 and Comparative Examples 4 to 6, were substantially lower than those from the cleaning composition that does not include a chelating agent according to Comparative Example 12 and the cleaning composition including only a surfactant according to Comparative Example 8. Further, etch rates of the tungsten layer and the aluminum layer from the cleaning composition including two types of the chelating agent according to Example 2 were relatively lower than those from the cleaning compositions including one the chelating agent according to Comparative Examples 4 to 6.

In Group III, etch rates of the tungsten layer and the aluminum layer from the cleaning compositions including two types of the chelating agents according to Examples 5 and 6, were substantially lower than those from the cleaning compositions that do not include a chelating agent according to Comparative Examples 14 and 15. Further, etch rates of the tungsten layer and the aluminum layer from the cleaning compositions including about 0.01 wt % of the hydrogen fluoride according to Example 5 and Comparative Example 14 were substantially lower than those of the tungsten layer and the aluminum layer from the cleaning composition including about 0.03 wt % of the hydrogen fluoride according to Example 6 and Comparative Example 15.

With regard to Examples 6 to 10 in Group IV, as contents of the chelating agents increase, etch rates of the tungsten layer and the aluminum layer were substantially reduced. The etch rates of the tungsten layer and the aluminum layer from the cleaning composition including about 10 wt % of the triazole and about 10 wt % of the glutamic acid according to Example 10 were substantially lower by about 75% to about 85% than those of the tungsten layer and the aluminum layer from the cleaning composition including about 1.0 wt % of the triazole and about 1.0 wt % of the glutamic acid according to Example 6. Although the etch rates of the tungsten layer and the aluminum layer may be reduced relative to an increase of the concentration of the chelating agents, stability of the cleaning composition may be considered as previously described with reference to Table 2.

Therefore, the cleaning composition of the present invention may be used in a cleaning process of a semiconductor substrate. As a result, damage to a metal layer including tungsten or aluminum may be effectively prevented and thus a sufficient process margin may be obtained.

According to the present invention, the cleaning composition may effectively remove a polymer and other residues from a metal layer and/or a semiconductor substrate and simultaneously may inhibit corrosion of the metal layer on the semiconductor substrate. Here, the semiconductor substrate may include the metal layer such as an aluminum layer, a titanium layer, a tungsten layer, etc., an insulation layer such as a silicon oxide layer and/or a polysilicon layer. In addition, the cleaning composition of the present invention may be advantageously applied to a single-type cleaning apparatus instead of a conventional batch-type cleaning apparatus so that a process time may be reduced and also the polymer and other residues may be effectively removed from the metal layer and/or the substrate. Therefore, failures of a semiconductor device may be prevented and productivity of a semiconductor device manufacturing process may be enhanced.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of cleaning a semiconductor substrate, comprising:
forming a metal-containing pattern structure on a semiconductor substrate; and
applying a cleaning composition to the semiconductor substrate that comprises, based on a total weight of the cleaning composition, about 78 wt % to about 99.98 wt % of an acidic aqueous solution, about 0.01 wt % to about 11 wt % of a first chelating agent, and about 0.01 wt % to about 11 wt % of a second chelating agent,
wherein the metal-containing pattern structure comprises an exposed first surface portion and a second surface portion covered with a polymer, and wherein application of the cleaning solution forms a first corrosion-inhibition layer on the first surface portion of the metal-containing pattern structure, and removes the polymer from the second surface portion of the metal-containing layer.

2. The method of claim 1, wherein the cleaning composition comprises, based on a total weight of the cleaning composition, about 90 wt % to about 99.8 wt % of the acidic aqueous solution, about 0.1 wt % to about 5 wt % of the first chelating agent, and about 0.1 wt % to about 5 wt % of the second chelating agent.

3. The method of claim 1, wherein the cleaning composition has a pH of about 0.1 to about 6.

4. The method of claim 1, wherein the first chelating agent comprises at least one of an azole compound, an amine compound and a sulfur-containing compound.

5. The method of claim 4, wherein the azole compound comprises at least one selected from the group consisting of a triazole compound including triazole, 1H-1,2,3-triazole, 1,2,3-triazole-4,5-dicarboxylic acid, 1,2,4-triazole, 1H-1,2,4-triazole-3-thiol and 3-amino-triazole; a benzotriazole compound including benzotriazole, 1-amino-benzotriazole, 1-hydroxy-benzotriazole, 5-methyl-1H-benzotriazole and benzotriazole-5-carboxylic acid; an imidazole compound including imidazole, 1-methyl imidazole, benzimidazole, 1-methyl-benzimidazole, 2-methyl-benzimidazole and 5-methyl-benzimidazole; a tetrazole compound including 1H-tetrazole, 1H-tetrazole-5-acetic acid and 5-amino-tetrazole; a thiazole compound including benzothiazole, 2-methyl-benzothiazole, 2-amino-benzothiazole, 6-amino-benzothiazole and 2-mercapto-benzothiazole; an oxazole compound including isoxazole, benzoxazole, 2-methyl-benzoxazole and 2-mercapto-benzoxazole; and a pyrazole compound including pyrazole and 4-pyrazole-carboxilic acid.

6. The method of claim 4, wherein the amine compound comprises at least one selected from the group consisting of methylamine, diethylamine, n-decylamine, morpholine, allylamine, pyridine, quinoline, imidazoline, hexamethyleneimene-m-nitrobenzoate, dicyclohexamine nitrite and 1-ethylamino-2-octadecylimidazoline, and
wherein the sulfur-containing compound comprises at least one selected from the group consisting of benzylmercaptan, phenylthiourea, di-sec-butylsulfide and diphenylsulfoxide.

7. The method of claim 1, wherein the second chelating agent comprises at least one amino acid compound selected from the group consisting of diethylenetriaminepentaacetic acid, glycine, alanine, valine, leucine, isoleucine, serine, threonine, tyrosine, phenylalanine, tryptophan, aspartic acid, glutamic acid, glutamine, asparagine, lysine, arginine, histidine, hydroxylysine, cysteine, methionine, cystine, proline, sulfamic acid and hydroxyproline

8. The method of claim 1, wherein the acidic aqueous solution comprises:
sulfuric acid;
at least one peroxide compound selected from the group consisting of hydrogen peroxide, ozone, peroxosulfuric acid, peroxoboric acid, peroxophosphoric acid and peracetic acid;
at least one fluorine-containing compound selected from the group consisting of hydrogen fluoride (HF), ammonium fluoride (NH₄F) and fluoroboric acid (HBF₄); and
pure water.

9. The method of claim 8, wherein the cleaning composition comprises:
about 0.01 wt % to about 30 wt % of the sulfuric acid:
about 0.01 wt % to about 20 wt % of the peroxide compound;
about 0.001 wt % to about 5 wt % of the fluorine-containing compound;
about 0.01 wt % to about 11 wt % of the first chelating agent;
about 0.01 wt % to about 11 wt % of the second chelating agent; and
the residual total wt % of the cleaning composition of pure water.

10. The method of claim 8, wherein the cleaning composition comprises:
about 0.1 wt % to about 10 wt % of the sulfuric acid:
about 0.1 wt % to about 10 wt % of the peroxide compound;
about 0.01 wt % to about 2 wt % of the fluorine-containing compound;
about 0.1 wt % to about 5 wt % of the first chelating agent;
about 0.1 wt % to about 5 wt % of the second chelating agent; and
the residual total wt % of the cleaning composition of pure water.

11. The method of claim 1, wherein a second corrosion-inhibition layer is formed on the second surface portion of the metal-containing pattern structure after removal of the polymer.

12. The method of claim 1, further comprising:
rinsing the semiconductor substrate from which the polymer thereon is removed; and
drying the semiconductor substrate.

13. The method of claim 1, wherein the polymer comprises at least one of an organic polymer, an oxide polymer and a metallic polymer.

14. The method of claim 1, wherein applying the cleaning composition to the semiconductor substrate is performed at a temperature of about 10° C. to about 40° C.

15. The method of claim 1, wherein applying the cleaning composition to the semiconductor substrate is carried out using a batch-type cleaning apparatus or a single-type cleaning apparatus.

16. The method of claim 1, wherein the metal-containing pattern structure on the semiconductor substrate makes contact with the cleaning composition in a single-type cleaning apparatus for about 0.01 minute to about 5 minutes.

17. The method of claim 1, wherein the metal-containing pattern structure comprises a bit line, a metal wiring, a gate electrode, a pad, or a contact.

18. The method of claim 1, wherein forming the metal-containing pattern structure comprises:
sequentially forming an oxide layer, a conductive layer and a mask layer on a semiconductor substrate including an isolation layer; and
dry etching the oxide layer, the conductive layer and the mask layer to form the metal-containing pattern structure including an oxide layer pattern, a conductive layer pattern and a mask pattern.

19. The method of claim 1, wherein forming the metal-containing pattern structure comprises:
sequentially forming a conductive layer and a mask layer on a semiconductor substrate including a contact pad and an insulation layer; and
dry etching the conductive layer and the mask layer to form the metal-containing pattern structure including a conductive layer pattern and a mask pattern.

20. The method of claim 19, further comprising:
rinsing the semiconductor substrate after applying the cleaning composition to the semiconductor substrate; and
drying the semiconductor substrate.
